(19) United States
(12) Patent Application Publication
(10) Pub. No.: US 2016/0161367 A1
(43) Pub. Date: Jun. 9, 2016

(54) DEVICE AND METHOD FOR DETECTING VEHICLE ENGINE STATE

(71) Applicant: INSTITUTE FOR INFORMATION INDUSTRY, TAIPEI (TW)

(72) Inventor: Yi-Hong CHU, Taipei City (TW)

(21) Appl. No.: 14/617,862

(22) Filed: Feb. 9, 2015

(30) Foreign Application Priority Data
Dec. 4, 2014 (CN) 201410733634.8

(51) Int. Cl. G01M 15/02; G01R 31/36

(52) U.S. Cl. CPC G01M 15/02; G01R 31/3644

(57) ABSTRACT

A device for detecting a vehicle engine state includes a power input terminal and a power monitoring unit. The power input terminal is electrically connected to a battery. The power monitoring unit is electrically connected to the power input terminal and configured to detect a battery voltage of the battery and to update a standby threshold voltage predefined in the power monitoring unit according to a standby level of the battery in a steady state whenever an engine shuts down. The power monitoring unit is configured to compare the detected battery voltage and the updated standby threshold voltage, and to determine if the engine is activated according to a result of the comparison. A vehicle engine state detecting method is also disclosed herein.

### RELATED APPLICATIONS

This application claims priority to China Application Serial Number 201410733634.8 filed Dec. 4, 2014, which is herein incorporated by reference.

### BACKGROUND

1. Technical Field

The present invention relates to a vehicle electronic device. More particularly, the present invention relates to a vehicle engine state detecting device.

2. Description of Related Art

Vehicle electronic devices in the market, such as On-Board Diagnostics (OBDs), vehicle operation recorders, vehicular navigation systems, Head-Up Displays (HUDs), etc. are powered by a vehicle battery. In order to prevent battery power from running out after shutting off the engine of the vehicle so that the vehicle cannot be started, the aforementioned vehicle electronic devices often include power management systems to place the vehicle electronic devices into a sleep mode when the vehicle electronic devices are not used for a long period of time. Thus, in order to wake up the vehicle electronic devices automatically when the engine is activated, the vehicle electronic devices have to determine whether the engine is activated while the vehicle electronic devices are in the sleep mode.

With improvements and breakthroughs in battery technology, the traditional method of engine activation determination using a fixed threshold voltage is not applicable to various battery types with different discharging modes and different voltage levels. In addition, due to the fact that the discharging characteristics of aged batteries and the discharging characteristics of normal batteries are different, after the battery has gradually aged, the traditional method cannot be used to effectively determine whether the engine is activated. Thus, there is a need in the field to design a detecting device applicable to batteries having deferent specifications and to aged batteries to effectively determine whether the engine is activated.

### SUMMARY

One aspect of the present disclosure is a vehicle engine state detecting device. According to an embodiment of the present disclosure, the vehicle engine state detecting device includes a power input terminal and a power monitoring unit. The power input terminal is electrically connected to a battery. The power monitoring unit is electrically connected to the power input terminal and configured to detect a battery voltage of the battery, and to update a standby threshold voltage predefined in the power monitoring unit according to a standby level of the battery in steady state whenever an engine shuts down. The power monitoring unit is configured to compare the detected battery voltage and the updated standby threshold voltage and to determine if the engine is activated according to a result of the comparison.

Another aspect of the present invention is a vehicle engine state detecting method. Steps of the vehicle engine state detecting method include detecting the battery voltage of the battery; detecting the standby level of the battery in steady state when the engine is determined to be in a shutdown state; updating the standby threshold voltage according to the standby level; comparing the detected battery voltage and the updated standby threshold voltage; and determining the engine is activated when the detected battery voltage is larger than the updated standby threshold voltage.

One another aspect of the present disclosure is a vehicle engine state detecting device. The vehicle engine state detecting device includes a power input terminal, a power monitoring unit, an operation unit and a timer. The power input terminal is configured to electrically connect to a battery. The power monitoring unit is electrically connected to the power input terminal and configured to detect a battery voltage of the battery and to update a standby threshold voltage predefined in the power monitoring unit whenever an engine shuts down according to a standby level of the battery in a steady state. The operation unit is electrically connected to the power monitoring unit and configured to perform arithmetic processing. The timer is electrically connected to the power monitoring unit and the operation unit and configured to provide a clock signal to the power monitoring unit and the operation unit. The power monitoring unit is configured to compare the detected battery voltage and the updated standby threshold voltage and to determine if the engine is activated according to a result of the comparison.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiments, with reference made to the accompanying drawings as follows:

FIG. 1 is a schematic diagram illustrating a vehicle engine state detecting device according to an embodiment of the present disclosure;

FIG. 2A is a schematic diagram illustrating voltage characteristics of a normal battery when activated and shut down according to an embodiment of the present disclosure;

FIG. 2B is a schematic diagram illustrating voltage characteristics of an old battery when activated and shut down according to an embodiment of the present disclosure;

FIG. 2C is a schematic diagram illustrating voltage characteristics of a new battery with protection design when activated and shut down according to an embodiment of the present disclosure;

FIG. 2D is a schematic diagram illustrating voltage characteristics of a battery when activated and shut down according to an embodiment of the present disclosure;

FIG. 3 is a flowchart illustrating a vehicle engine state detecting method according to an embodiment of the present disclosure;

FIG. 4 is a schematic diagram illustrating a vehicle engine state detecting device according to another embodiment of the present disclosure;

FIG. 5 is a flowchart illustrating an operating method of the vehicle engine state detecting device according to an embodiment of the present disclosure; and

FIG. 6 is a flowchart illustrating an operating method of the vehicle engine state detecting device according to another embodiment of the present disclosure.

### DETAILED DESCRIPTION

Reference will now be made in detail to embodiments of the present disclosure, examples of which are described herein and illustrated in the accompanying drawings. While the disclosure will be described in conjunction with embodiments, it will be understood that they are not intended to limit the invention to these embodiments. On the contrary, the invention is intended to cover alternatives, modifications and equivalents, which may be included within the spirit and scope of the disclosure as defined by the appended claims. It is noted that, in accordance with the standard practice in the industry, the drawings are only used for understanding and are not drawn to scale. Hence, the drawings are not meant to limit the actual embodiments of the present disclosure. In fact, the dimensions of the various features may be arbitrarily increased or reduced for clarity of discussion. Wherever possible, the same reference numbers are used in the drawings and the description to refer to the same or like parts for better understanding.

The terms used in this specification and claims, unless otherwise stated, generally have their ordinary meanings in the art, within the context of the disclosure, and in the specific context where each term is used. Certain terms that are used to describe the disclosure are discussed below, or elsewhere in the specification, to provide additional guidance to the practitioner skilled in the art regarding the description of the disclosure.

The terms “about” and “approximately” in the disclosure are used as equivalents. Any numerals used in this disclosure with or without “about,” “approximately,” etc. are meant to cover any normal fluctuations appreciated by one of ordinary skill in the relevant art. In certain embodiments, the term “approximately” or “about” refers to a range of values that fall within 20%, 10%, 5%, or less in either direction (greater or less than) of the stated reference value unless otherwise stated or otherwise evident from the context.

In the following description and in the claims, the terms “include” and “comprise” are used in an open-ended fashion, and thus should be interpreted to mean “include, but not limited to.” As used herein, the term “and/or” includes any and all combinations of one or more of the associated listed items.

In this document, the term “coupled” may also be termed “electrically coupled,” and the term “connected” may be termed “electrically connected.” “Coupled” and “connected” may also be used to indicate that two or more elements cooperate or interact with each other. It will be understood that, although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments.

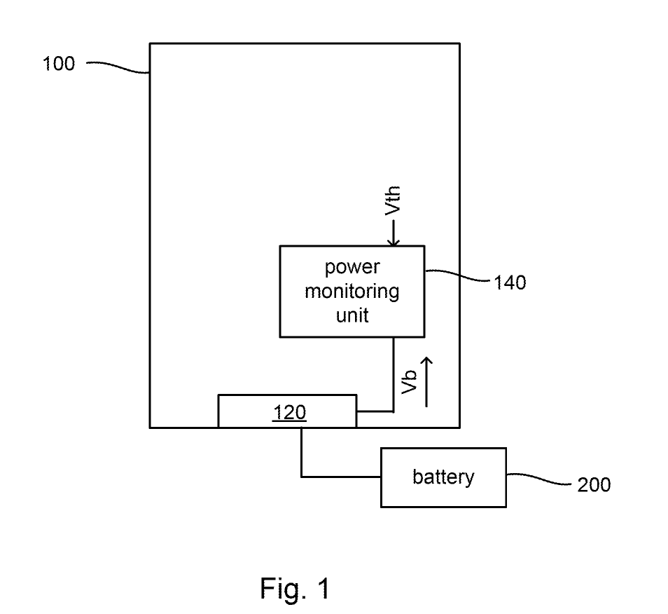

Reference is made to FIG. 1. FIG. 1 is a schematic diagram illustrating a vehicle engine state detecting device 100 according to an embodiment of the present disclosure. In the present embodiment, the vehicle engine state detecting device 100 includes a power input terminal 120 and a power monitoring unit 140. The power monitoring unit 140 is electrically connected to the power input terminal 120. The power input terminal 120 of the vehicle engine state detecting device 100 is configured to be electrically connected to a battery 200. The power monitoring unit 140 is configured to detect a battery voltage Vb of the battery 200 through the power input terminal 120, and to determine whether an engine is activated according to the detected battery voltage Vb and a standby threshold voltage Vth. Each time when the engine shuts down, the power monitoring unit 140 is configured to update the standby threshold voltage Vth according to a standby level V1 of the battery voltage Vb.

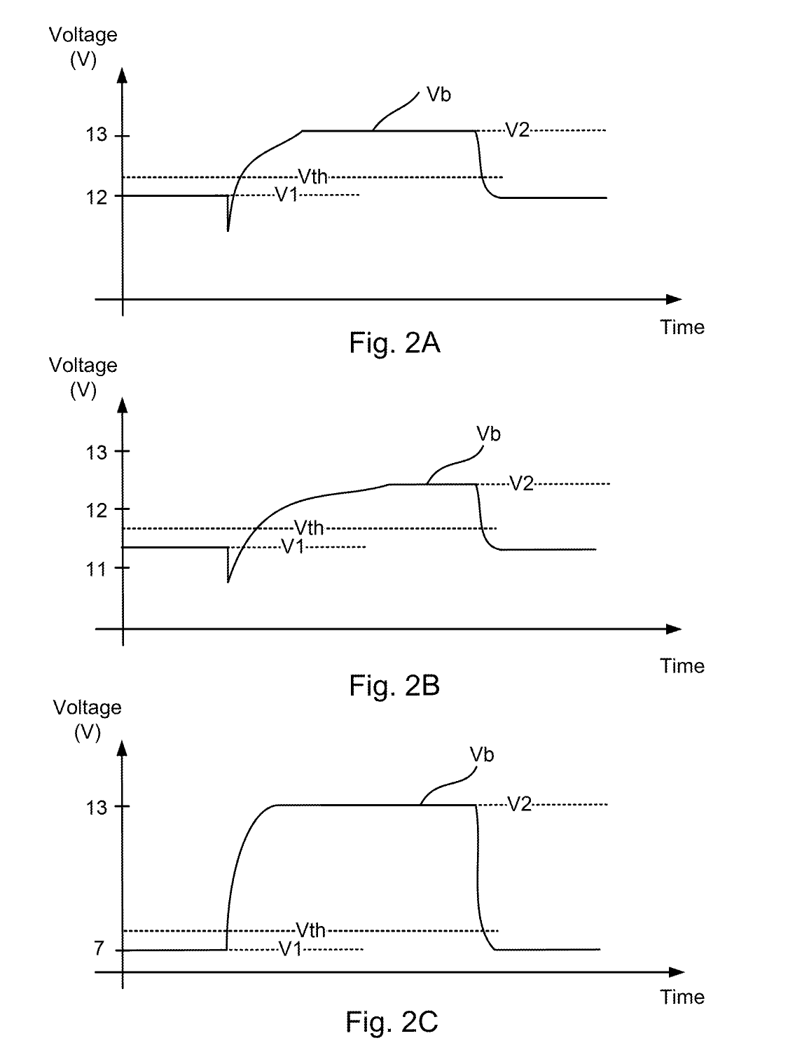

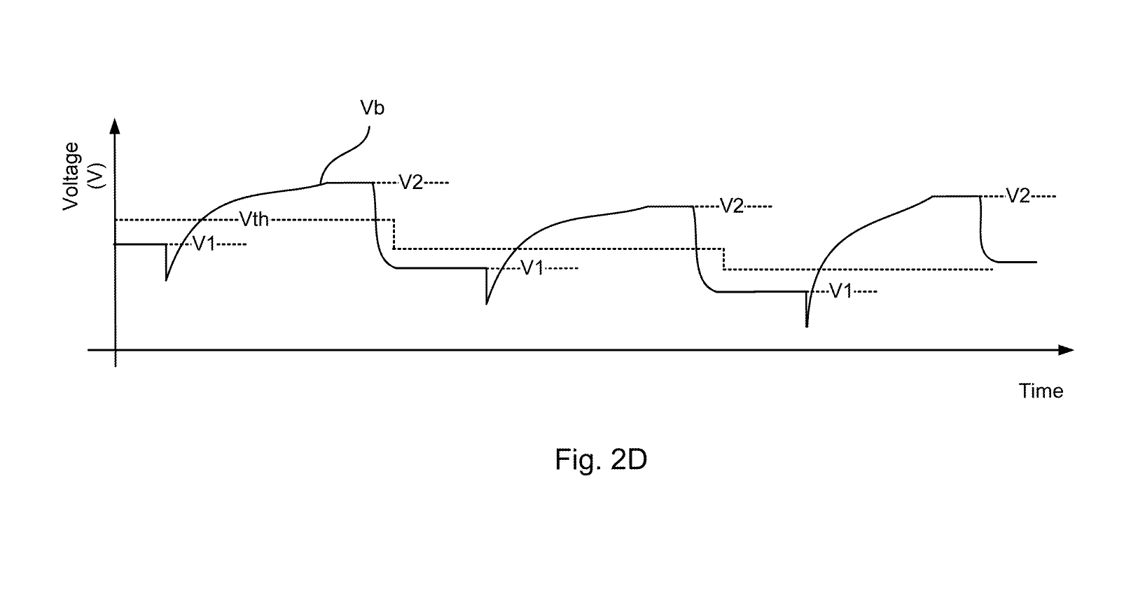

Additional reference is made to FIG. 2A˜FIG. 2D. FIG. 2A˜FIG. 2D are schematic diagrams illustrating voltage characteristics of various batteries when activated and shut down. The voltage characteristics of a battery 200 in FIG. 2A˜FIG. 2D will be described respectively in the following paragraphs. FIG. 2A is a schematic diagram illustrating voltage characteristics of a normal battery 200 when activated and shut down according to an embodiment of the present disclosure. As shown in FIG. 2A, under normal conditions, for the battery 200 commonly found in the market, the standby level V1 of the battery 200 is, for example, about 12 volts. After the engine is activated, a voltage sag occurs in the battery 200 in a transient state, and then the voltage rises to a working level V2 and into a steady state. Generally speaking, the working level V2 of the battery 200 is about 13 to 14 volts.

As shown in FIG. 2B, after the battery 200 has aged gradually with frequent use, when the engine is not activated, the standby level V1 is lower than 12 volts and degraded to around 11 volts, for example, and a longer charging time is required to raise the voltage of the battery 200 to the steady state working level V2. As shown in FIG. 2B, the working level V2 of the battery 200 after aging is also lower than the working level V2 of the normal battery 200.

In addition, as shown in FIG. 2C, some new batteries 200 in use have a protection design, such that the voltage sag phenomenon shown in FIG. 2A and FIG. 2B is prevented, and the standby level V1 of the battery 200 is lower (i.e., 7 volts). By lowering the standby level V1 and preventing a voltage sag, vehicles utilizing the battery 200 shown in FIG. 2C can achieve functions such as extending the standby period of the battery 200 and protecting vehicle electronic devices.

In some other examples, as shown in FIG. 2D, after aging gradually with frequent use, some batteries 200 do not fall back to the same standby level V1 as the former standby level V1 each time the engine shuts down, and instead, the standby level V1 degrades or shifts.

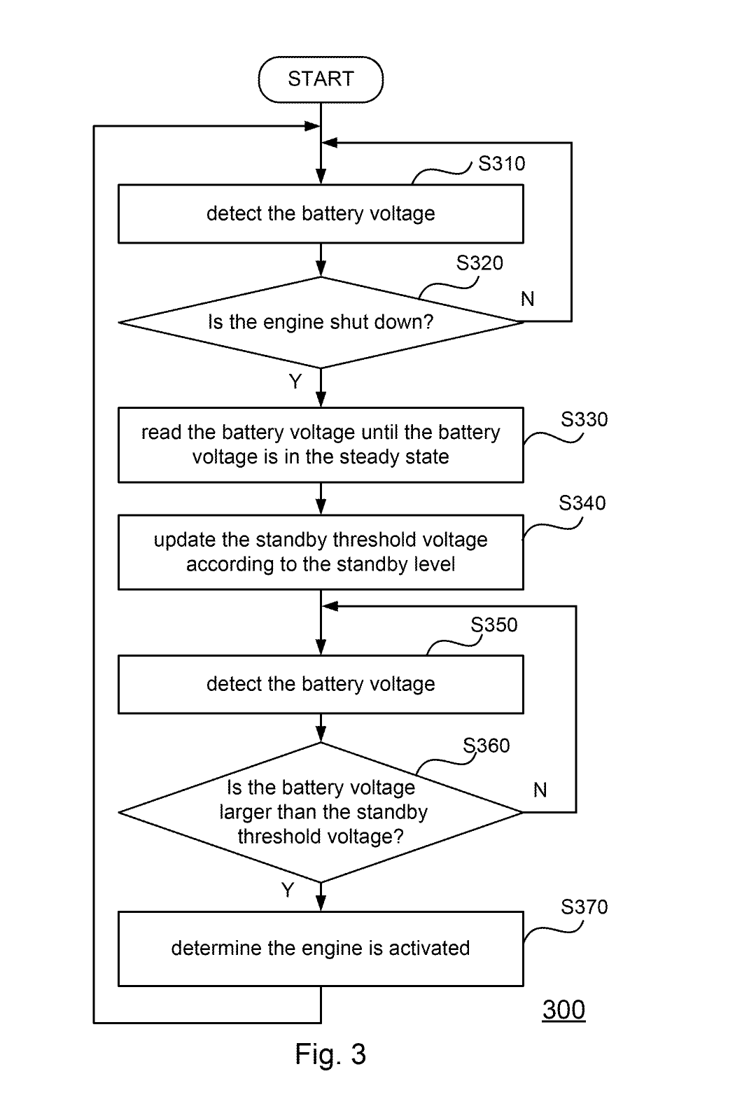

In the present embodiment, the vehicle engine state detecting device 100 is applicable to batteries having different voltage characteristics shown in FIG. 2A˜FIG. 2D, and is configured to determine the activating operation or shutdown operation of the engine according to the change in the battery voltage Vb. FIG. 3 is a flowchart illustrating a vehicle engine state detecting method 300 according to an embodiment of the present disclosure. The vehicle engine state detecting method 300 includes steps S310, S320, S330, S340, S350, S360 and S370, which will be described in detail in the paragraphs below. For convenience and clarity of explanation, the following vehicle engine state detecting method 300 is discussed in relation to the embodiment shown in FIG. 1 and FIG. 2A˜FIG. 2D, but is not limited thereto. It will be apparent to those skilled in the art that various modifications and variations can be made to the structure of the present disclosure without departing from the scope or spirit of the disclosure.

First, in step S310, as shown in FIG. 1 and FIG. 2A˜FIG. 2D, when the power input terminal 120 is electrically connected to the battery 200, the power monitoring unit 140 may be configured to detect the battery voltage Vb of the battery 200. Next, in step S320, the power monitoring unit 140 is configured to determine whether the engine is shut down according to the change in the battery voltage Vb.

The step of the power monitoring unit 140 determining whether the engine is shut down according to the change in the battery voltage Vb can be achieved by various ways. For example, the power monitoring unit 140 may be configured to set an additional working threshold voltage such that the power monitoring unit 140 determines the engine is shut down when the detected battery voltage Vb is smaller than the working threshold voltage. In addition, in another embodiment, the power monitoring unit 140 may also determine that the engine is shut down when detecting a rapid drop in the battery voltage over a short time period. This method may be applied to batteries 200 having different working levels (i.e., 12 volts and 24 volts)

When the power monitoring unit 140 determines that the engine is shut down according to the change in the battery voltage Vb, step S330 is performed and the power monitoring unit 140 continues reading the battery voltage Vb of the battery 200 until the battery 200 is in the steady state. That is to say, the power monitoring unit 140 may be operated in a standby voltage self-adjusting mode.

Next, in step S340, the power monitoring unit 140 is configured to update the standby threshold voltage Vth according to the standby level V1 of the battery 200 in the steady state. For example, in an embodiment of the present disclosure, the standby threshold voltage may be set to be the standby level V1 of the battery 200 after shutting down plus a tolerance error value of 5%. That is to say, assuming the voltage characteristics of the battery 200 is as shown in FIG. 2A, when the power monitoring unit 140 determines that the voltage value of the battery 200 has fallen and is stable at 12 volts (V), the standby threshold voltage Vth may be set according to the steady state voltage value of 12 volts plus the tolerance error value of 0.6 volts, i.e., 12.6 volts.

On the other hand, if the voltage characteristics of the battery 200 are as shown in FIG. 2C, when the power monitoring unit 140 determines that the voltage value of the battery 200 has fallen and is stable at 7 volts (V), the standby threshold voltage Vth may be set according to the standby level V1 of 7 volts plus the tolerance error value of 0.35 volts, i.e., 7.35 volts.

Next, in step S350, the power monitoring unit 140 continues detecting the battery voltage Vb of the battery 200 after the engine has shut down. Subsequently, in step S360, the power monitoring unit 140 determines whether the battery voltage Vb is larger than the standby threshold voltage Vth. If the battery voltage Vb is still smaller than the standby threshold voltage Vth, the power monitoring unit 140 determines that the engine is still in the shutdown state and continues repeating steps S350 and S360 of detecting and determining whether the battery voltage Vb is larger than the standby threshold voltage Vth.

When the power monitoring unit 140 detects that the battery voltage Vb of the battery 200 exceeds the standby threshold voltage Vth, step S370 is performed and the power monitoring unit 140 determines that the engine is activated. After determining that the engine is activated, the process returns to step S310, and the power monitoring unit 140 continues detecting the battery voltage Vb of the battery 200 and determining when the engine is in the shutdown state.

Therefore, due to the fact that the standby threshold voltage Vth is configured to be updated according to the stable standby level V1 the voltage of the battery 200 falls into each time after shutting down, regardless of whether the vehicle is employing the widely used traditional battery having the standby level V1 of about 12 volts as shown in FIG. 2A, the old battery having the lower standby level V1 as shown in FIG. 2B, or the new battery with protection design having the standby level V1 of about 7 volts as shown in FIG. 2C, the vehicle engine state detecting device 100 is able to set and update the corresponding standby threshold voltage Vth and to determine whether the engine is activated.

In addition, even if the standby level V1 of the battery 200, as shown in FIG. 2D, degrades or floats each time after shutting down due to aging and cannot return to the original standby level V1, because the power monitoring unit 140 is configured to update the standby threshold voltage Vth each time after shutting down, the corresponding standby threshold voltage Vth is updated according to the shifting standby level V1 and the power monitoring unit 140 is still able to determine the engine activation a subsequent time accurately and effectively.

In the present embodiment, the power monitoring unit 140 may be implemented by an embedded system. For example, the power monitoring unit 140 may be implemented by an analog-to-digital converter (ADC) or a micro control unit (MCU) with an ADC installed therein. When the vehicle engine state detecting device 100 is used in a vehicle electronic device including a MCU, the vehicle engine state detecting device 100 may also be implemented by the MCU of the vehicle electronic device.

It is noted that by setting the tolerance error value to 5%, the erroneous determination of the engine state by the power monitoring unit 140 due to noise causing fluctuations in the detected battery voltage Vb is prevented. Thus, the tolerance error value may be flexibly set from 1% to 5%, for example, 1% or 3%, depending on actual needs. The tolerance error value may also be set to a reasonable value, such as 0.3 volts or 0.5 volts. It is noted that the values indicated in the present embodiment are provided merely for example and for the sake of convenience, and are not meant to limit the present disclosure. For example, the vehicle state detecting method 300 is not only applicable to cars using a 12V battery, but also applicable to large vehicles such as trucks using a 24V battery.

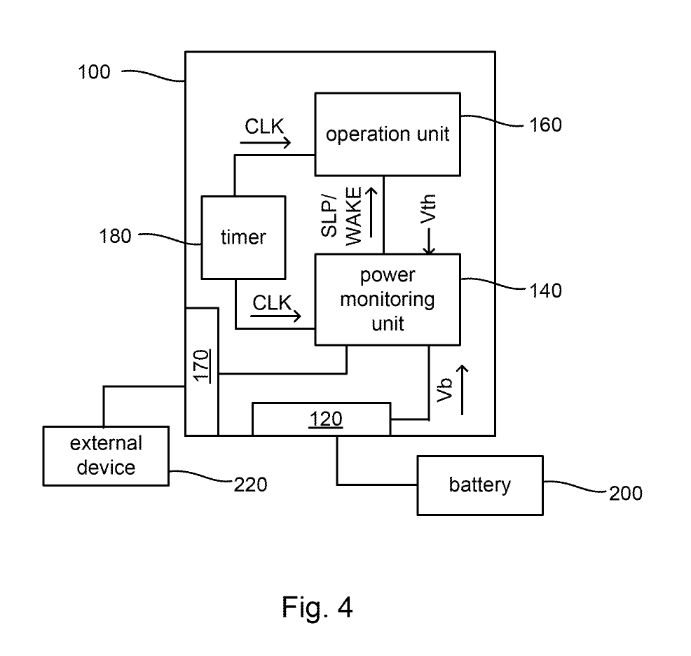

Reference is made to FIG. 4. FIG. 4 is a schematic diagram illustrating the vehicle engine state detecting device 100 according to another embodiment of the present disclosure. Compared to the embodiment shown in FIG. 1, in the present embodiment, the vehicle engine state detecting device 100 further includes an operation unit 160. The operation unit 160 is electrically connected to the power monitoring unit 140, and is configured to perform a corresponding arithmetic processing according to the needs of different vehicle electronic devices such as On-Board Diagnostics (OBDs), vehicle operation recorders, vehicular navigation systems, Head-Up Displays (HUDs), etc.

In the present embodiment, due to the fact that the operation unit 160 consumes the electricity of the battery 200, the power monitoring unit 140 is further configured to send a sleep command SLP to the operation unit 160 such that the operation unit 160 and the vehicle electronic device operate in a sleep mode when the engine shuts down to prevent consumption of the electricity of the battery 200, and only the operation of the power monitoring unit 140, which consumes a low amount of power, is maintained for detecting the battery voltage Vb of the battery 200 periodically.

For example, in the embodiment of the power monitoring unit 140 including the ADC, the ADC may be configured to send a corresponding signal to the operation unit 160 to interrupt the operation process of the operation unit 160 and place the same in the sleep mode.

As described in the aforementioned embodiment, the power monitoring unit 140 may determine whether the engine is activated according to the characteristics of the battery voltage Vb of the battery 200 exceeding the standby threshold voltage Vth. In the present embodiment, the power monitoring unit 140 is further configured to send a wake command WAKE to the operation unit 160. After the operation unit 160 receives the wake command WAKE, the vehicle electronic device is activated automatically. For example, in the embodiment of the power monitoring unit 140 including the ADC, the power monitoring unit 140 may be configured to send a corresponding signal to wake up the operation unit 160 from sleep mode.

Therefore, by installing the vehicle engine state detecting device, users do not need to operate the physical switch of each of the vehicle electronic devices separately. A variety of vehicle electronic devices using the power supplied from the battery 200, including On-Board Diagnostics (OBDs), vehicle operation recorders, vehicular navigation systems, Head-Up Displays (HUDs), etc., may operate in the sleep mode automatically when the engine shuts down, and may automatically activate their functions and operate normally when the engine is activated again.

Reference is again made to FIG. 4. In an embodiment, the vehicle engine state detecting device 100 includes an external terminal 170. The external terminal 170 is electrically connected to the power monitoring unit 140 and configured to be electrically connected to an external device 220 (i.e., mobile phones, tablets, etc.). For example, the external terminal may be a universal serial bus (USB) terminal. The vehicle engine state detecting device 100 may be configured to provide functions such as charging or data transmitting to the external device 220.

In an embodiment, when the power monitoring unit 140 determines that the engine has shut down, the vehicle engine state detecting device 100 is configured to stop supplying power to the external device 220. On the other hand, when the power monitoring unit 140 determines that the engine is activated, the vehicle engine state detecting device 100 is configured to supply power to the external device 220 via the external terminal 170, and to trigger and drive the external device 220 using electricity. In other words, the power monitoring unit 140 disclosed in the present disclosure may be configured to process various operations according to the determined engine state and is not limited to sending the wake command WAKE and sleep command SLP.

Reference is again made to FIG. 4. In an embodiment, the vehicle engine state detecting device 100 further includes a timer 180. The timer 180 is electrically connected to the power monitoring unit 140. In some embodiments, the timer 180 is also electrically connected to the operation unit 160.

In the present embodiment, the timer 180 is configured to send a clock signal CLK to the power monitoring unit 140 and the operation unit 160. The power monitoring unit 140 may be configured to use the clock signal CLK provided by timer 180 to detect the battery voltage Vb of the battery 200 periodically. The operation unit 160 may be configured to use the clock signal CLK provided by timer 180 to process operations, synchronize information, clean system errors, etc.

For example, when the vehicle engine state detecting device 100 is applied to a vehicle operation recorder, the clock signal CLK provided by the timer 180 may be used to synchronize the image information and the sound information recorded by the vehicle operation recorder. In another embodiment, when the vehicle engine state detecting device 100 is applied in a vehicle monitoring system, the clock signal CLK provided by the timer 180 may be used to record the time when the vehicle monitoring data is found to be abnormal.

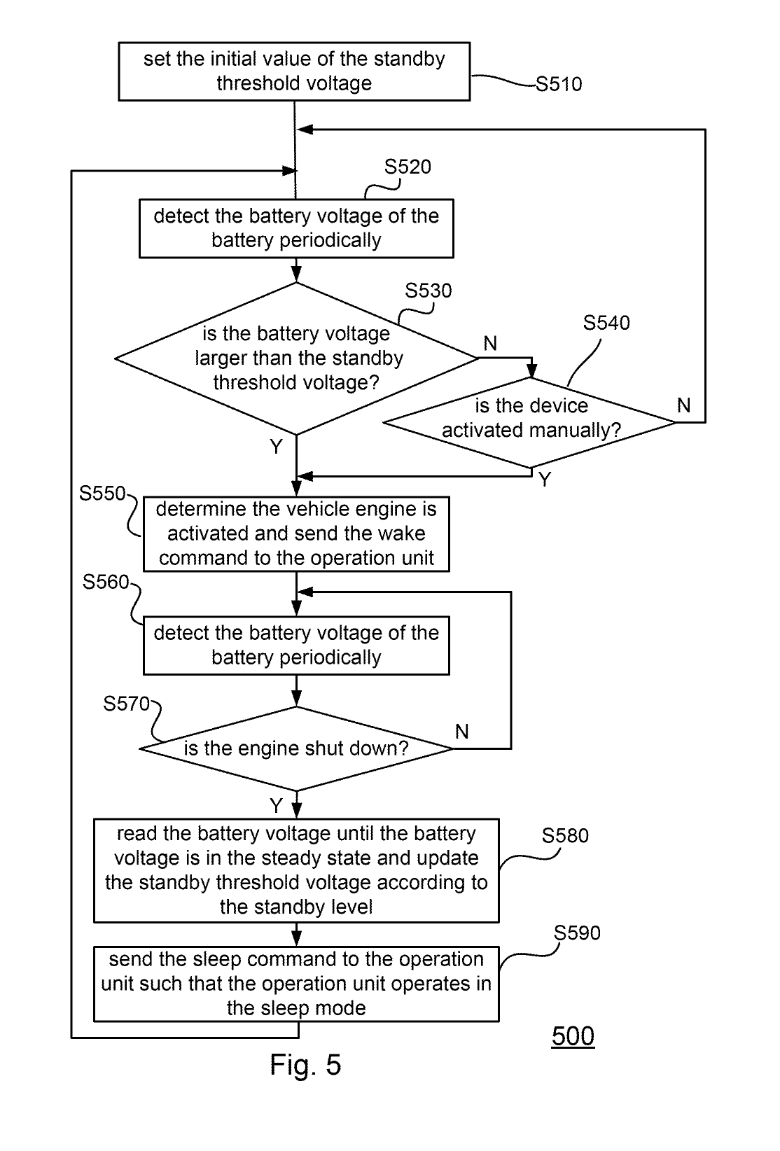

Reference of the specific operating process of the vehicle engine state detecting device 100 is made to FIG. 5. FIG. 5 is a flowchart illustrating a vehicle engine state detecting method 500 according to an embodiment of the present disclosure. The vehicle engine state detecting method 500 includes steps S510, S520, S530, S540, S550, S560, S570, S580 and S590.

First, in step S510, when the vehicle engine state detecting device 100 is electrically connected to the battery 200 for the first time, the power monitoring unit 140 is configured to set the initial value of the standby threshold voltage Vth.

For example, the power monitoring unit 140 may be configured to set the initial value of the standby threshold voltage Vth to be the battery voltage Vb detected for the first time plus the tolerance error value (i.e., 5% of the detected battery voltage). In other words, the power monitoring unit 140 may assume the vehicle engine is not activated at present, and the battery voltage Vb can be considered as the standby level V1 of the battery 200.

Next, in step S520, the power monitoring unit 140 is configured to detect the battery voltage Vb of the battery 200 periodically. In step S530, the power monitoring unit 140 is configured to determine whether the battery voltage Vb is larger than the standby threshold voltage Vth. When the battery voltage Vb is larger than the standby threshold voltage Vth, step S550 is performed and the power monitoring unit 140 determines that the vehicle engine is activated and sends the wake command WAKE to the operation unit 160.

If the vehicle engine is already activated when the vehicle engine state detecting device 100 is connected to the battery 200, due to the fact that the detected voltage of the battery 200 is already at the working level V2, the power monitoring unit 140 will not detect the battery voltage Vb exceeding the standby threshold voltage Vth. In other words, the standby threshold voltage Vth is mistakenly set to be higher than the working level V2 of the battery 200. Thus, in some embodiments, the vehicle engine state detecting method 500 includes step S540 of further determining whether the user activated the device manually or used the physically power switch to manually activate the device. If the user activated the device manually, step S550 is also performed, which involves correspondingly sending the wake command WAKE to the operation unit 160.

Next, in step S560, after the engine is determined to be activated, the vehicle electronic device (i.e., vehicle operation recorders, vehicular navigation systems, Head-Up Displays (HUDs), etc.) may process normally and the power monitoring unit 140 continues detecting the battery voltage Vb of the battery 200 periodically.

In step S570, the power monitoring unit 140 is configured to determine whether the vehicle engine has shut down and the battery voltage Vb has fallen back to the standby level V1, and is further configured to be operated in the standby voltage self-adjusting mode (in step S580 described directly below).

As shown in step S580, in the standby voltage self-adjusting mode, the power monitoring unit 140 continues detecting the battery voltage Vb of the battery 200 until the voltage of the battery 200 is in the steady state standby level V1, and updates the standby threshold voltage Vth according to the standby level V1.

Next, in step S590, the power monitoring unit 140 sends the sleep command SLP to the operation unit 160 such that the operation unit 160 and the vehicle electronic device are configured to operate in the sleep mode, thereby preventing the consumption of the electricity of the battery 200.

After the operation unit 160 and the vehicle electronic device go into the sleep mode, step S520 is once again performed, and the power monitoring unit 140 continues detecting the battery voltage Vb of the battery 200 periodically until the vehicle engine is determined to be activated and the wake command WAKE is sent to the operation unit 160 when the battery voltage Vb is again larger than the updated standby threshold voltage Vth to complete a cycle.

By the aforementioned process, even if the standby threshold voltage Vth is not set at the correct level when the vehicle engine state detecting device 100 is initially installed and the user has to wake up the operation unit 160 manually, the power detecting unit 140 is still able to update and adjust the standby threshold voltage Vth to a proper level automatically after one complete cycle.

In the aforementioned embodiment, the initialization of the standby threshold voltage may also be completed in other ways. For example, according to another embodiment of the present disclosure, in step S510, the power monitoring unit 140 may also be configured to set a default initializing value as the standby threshold voltage Vth during initialization. For example, according to the standby level V1 (i.e., 12 volts) of the battery commonly found in the market, the default initializing value may considered to be set to 12.6 volts.

Similar to the aforementioned embodiment, when the standby threshold voltage Vth is set correctly, the power monitoring unit 140 may detect that the battery voltage is larger than the standby threshold voltage Vth, determine that the vehicle engine is activated, and send the wake command WAKE to the operation unit 160 to complete one activation cycle.

If the power monitoring unit 140 does not set the standby threshold voltage Vth at the proper level initially, the vehicle engine state detecting device 100 may not be able to correctly determine whether the vehicle engine is activated.

For example, the default initializing value may be set to be 12.6 volts according to the standby level V1 of the battery commonly used for cars, but the actual standby level V1 of the battery 200 is 7 volts (i.e., the battery shown in FIG. 2C) or 24 volts (i.e., the battery used for large vehicles), etc.

When the power monitoring unit 140 does not set the standby threshold voltage Vth at the proper level, through waking up the operation unit 160 manually by the user, similar to the aforementioned embodiment, the power detecting unit 140 may still be able to update and adjust the standby threshold voltage Vth to a proper level automatically after the engine shuts down.

Typically, under circumstances where the engine has not been activated for a long time period, the standby level V1 of the battery 200 may possibly degrade slightly such that the difference between the standby level V1 and the standby threshold voltage Vth increases. Nevertheless, the battery voltage Vb still exceeds the standby threshold voltage Vth when the engine is activated, and therefore the vehicle engine state detecting method disclosed in the present disclosure is still able to detect the activation of the engine.

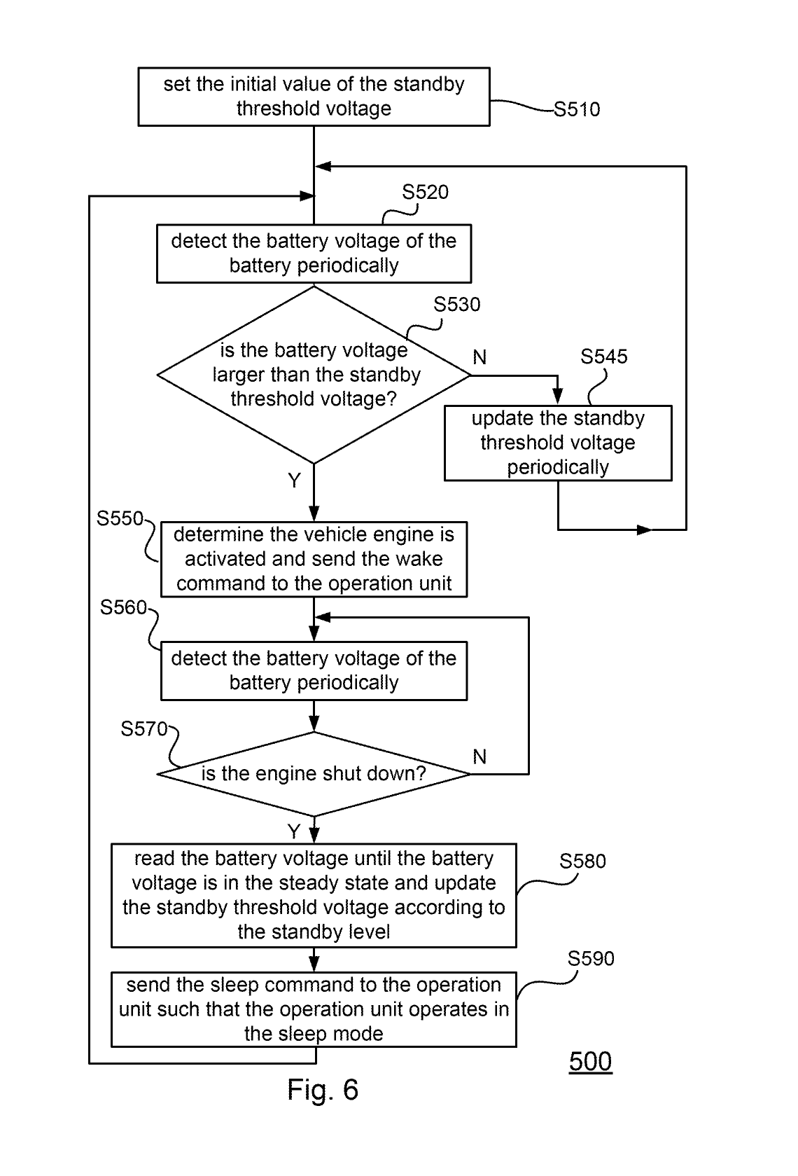

Reference is made to FIG. 6. FIG. 6 is a flowchart illustrating the vehicle engine state detecting method 500 according to another embodiment of the present disclosure. In the present disclosure, the vehicle engine state detecting method 500 may further include step S545 of maintaining the difference between the standby level V1 of the battery 200 and the standby threshold voltage Vth so the difference does not increase with time.

In step S545, the power monitoring unit 140 may be configured to set the cycle of updating the standby threshold voltage Vth periodically through the timer 180 in a state where the engine is in a shutdown state. In other words, the power monitoring unit 140 may be configured to detect the change of the battery voltage Vb (i.e., the actual standby level V1) when the battery 200 is in standby, and to update the standby threshold voltage Vth periodically according to the battery voltage Vb (Le., the actual standby level V1).

Thus, the power monitoring unit 140 still updates the standby threshold voltage Vth periodically when the system is in a sleep mode, and the difference between the standby threshold voltage Vth and the actual standby level V1 does not increase with the time in a state where the engine has not been activated for a long time period. By the aforementioned steps, the vehicle engine state detecting device 100 may operate more accurately when determining engine activation, and the response time of detection may also be reduced.

The above illustrations include exemplary operations, but the operations are not necessarily performed in the order described. The order of the operations disclosed in the present disclosure may be changed, or the operations may even be executed simultaneously or partially simultaneously as appropriate, in accordance with the spirit and scope of various embodiments of the present disclosure.

In the present disclosure, by applying the embodiments described above, a determination as to whether the vehicle engine is activated can be made by simply detecting the battery voltage, and no additional vehicle information interface such as On-Board Diagnostics (OBDs) or a controller area network (CAN or CAN bus) are needed. Therefore, fast response and low cost are achieved.

In addition, in the present disclosure, by using the method of updating the standby threshold voltage according to the battery voltage each time the engine shuts down and determining the engine state by the power monitoring unit according to the comparison of the detected battery voltage and the standby threshold voltage, a variety of vehicle battery discharging modes may be applicable in a single detecting condition, and the activation of the engine may be determined accurately when battery aging or standby voltage degrading situations are encountered, and applied in various vehicle electronic devices powered by the vehicle battery.

Although the disclosure has been described in considerable detail with reference to certain embodiments thereof, it will be understood that the embodiments are not intended to limit the disclosure. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A vehicle engine state detecting device, comprising:
a power input terminal configured to electrically connect to a battery; and
a power monitoring unit electrically connected to the power input terminal and configured to detect a battery voltage of the battery and to update a standby threshold voltage predefined in the power monitoring unit whenever an engine shuts down according to a standby level of the battery in a steady state;
wherein the power monitoring unit is configured to compare the detected battery voltage and the updated standby threshold voltage and to determine if the engine is activated according to a result of the comparison.

2. The vehicle engine state detecting device of claim 1, further comprising:
a timer electrically connected to the power monitoring unit and configured to provide a clock signal to the power monitoring unit;
wherein the power monitoring unit detects the battery voltage of the battery periodically according to the clock signal.

3. The vehicle engine state detecting device of claim 1, further comprising:
a timer electrically connected to the power monitoring unit and configured to provide a clock signal to the power monitoring unit such that the power monitoring unit detects and updates the standby level of the battery periodically, and updates the standby threshold voltage according to the standby level.

4. The vehicle engine state detecting device of claim 1, further comprising:
an operation unit electrically connected to the power monitoring unit and configured to perform arithmetic processing;
wherein the power monitoring unit is further configured to send a sleep command to the operation unit such that the operation unit operates in a sleep mode when the engine shuts down, and to send a wake command to the operation unit to wake up the operation unit when the engine is activated.

5. The vehicle engine state detecting device of claim 1, wherein the updated standby threshold voltage is set to be the standby level of the battery plus a tolerance error value.

6. A vehicle engine state detecting method comprising:
detecting a battery voltage of a battery;
detecting a standby level of the battery in steady state when an engine is determined to be in a shutdown state;
updating a standby threshold voltage according to the standby level;
comparing the detected battery voltage and the updated standby threshold voltage; and
determining the engine is activated when the detected battery voltage is larger than the updated standby threshold voltage.

7. The method of claim 6, further comprising:
detecting and updating the standby level of the battery periodically and updating the standby threshold voltage according to the standby level when the engine is in the shutdown state.

8. The method of claim 6, wherein updating the standby threshold voltage according to the standby level comprises:
setting the standby threshold voltage to be the standby level plus a tolerance error value.

9. The method of claim 6, further comprising:
sending a sleep command to a vehicle electronic device such that the vehicle electronic device operates in a sleep mode when the engine is determined to be shut down; and
sending a wake command to wake up the vehicle electronic device when the engine is determined to be activated.

10. A vehicle engine state detecting device, comprising:
a power input terminal configured to electrically connect to a battery;
a power monitoring unit electrically connected to the power input terminal and configured to detect a battery voltage of the battery and to update a standby threshold voltage predefined in the power monitoring unit whenever an engine shuts down according to a standby level of the battery in a steady state;
an operation unit electrically connected to the power monitoring unit and configured to perform arithmetic processing; and
a timer electrically connected to the power monitoring unit and the operation unit, and configured to provide a clock signal to the power monitoring unit and the operation unit;
wherein the power monitoring unit is configured to compare the detected battery voltage and the updated standby threshold voltage and to determine if the engine is activated according to a result of the comparison.

11. The vehicle engine state detecting device of claim 10, wherein the power monitoring unit detects the battery voltage of the battery periodically according to the clock signal.

12. The vehicle engine state detecting device of claim 10, wherein the operation unit performs arithmetic processing according to the clock signal.

13. The vehicle engine state detecting device of claim 10, wherein the power monitoring unit is further configured to send a sleep command to the operation unit such that the operation unit operates in a sleep mode when the engine shuts down, and to send a wake command to the operation unit to wake up the operation unit when the engine is activated.

14. The vehicle engine state detecting device of claim 10, wherein the updated standby threshold voltage is set to be the standby level of the battery plus a tolerance error value.
